(19) United States
(12) Patent Application Publication
(10) Pub. No.: US 2016/0064652 A1
(43) Pub. Date: Mar. 3, 2016

(54) THREE-TERMINAL STT-MRAM AND METHOD TO MAKE THE SAME

(71) Applicant: YIMIN GUO, SAN JOSE, CA (US)

(72) Inventor: YIMIN GUO, SAN JOSE, CA (US)

(73) Assignee: T3MEMORY, INC., Saratoga, CA (US)

(21) Appl. No.: 14/475,576

(22) Filed: Sep. 3, 2014

(51) Int. Cl. H01L 43/08; H01L 43/10; H01L 43/12; H01L 43/02

(52) U.S. Cl. CPC H01L 43/08; H01L 43/02; H01L 43/10; H01L 43/12

(57) ABSTRACT

This invention is to make a three-terminal perpendicular spin transfer torque magnetic random access memory (pSTT-MRAM) with a magnetic reference layer at bottom. The first electrode (digital line) is connected to a magnetic reference layer at the bottom, and the second electrode is located at the middle memory layer which is connected to the underneath CMOS circuit through VIA and the third electrode is a voltage gate connecting to the top bit line which is used to reduce the write current when a voltage is applied between the top and middle electrode.

### RELATED APPLICATIONS

This application claims the priority benefit of U.S. Provisional Application No. 61/874,076 filed on Sep. 5, 2013, which is incorporated herein by reference.

### BACKGROUND OF THE INVENTION

1. Field of the Invention

This invention relates generally to a three terminal magnetic-random-access memory (MRAM) cell, more particularly to methods of fabricating three terminal MRAM memory elements having ultra-small dimensions.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer is smaller, the injected spin-polarized current to write or switch can be also smaller.

Besides a write current, the stability of the magnetic orientation in a MRAM cell as another critical parameter has to be kept high enough for a good data retention, and is typically characterized by the so-called thermal factor which is proportional to the energy barrier as well as the volume of the recording layer cell size.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus unintentionally reversing the direction of magnetization of the recording layer in MTJ.

Above issues or problems are all associated with the traditional two-terminal MRAM configuration. Thus, it is desirable to provide robust STT-MRAM structures and methods that realize highly-accurate reading, highly-reliable recording and low power consumption while suppressing destruction and reduction of life of MTJ memory device due to recording in a nonvolatile memory that performs recording resistance changes, and maintaining a high thermal factor for a good data retention.

It is known that perpendicular magnet (PM) spin transfer torque magnetic random access memory (pSTT-MRAM) is an ideal memory for future semiconducting device. Current pSTT-MRAM is a two-terminal device with magnetic memory layer and reference layer separated by a thin MgO dielectric layer to form a so-called magnetic tunneling junction (MTJ). The shortcomings of such two-terminal pSTT-MRAM are its large critical write current and narrow current separation between read and write process. It has been recently reported that by applying a bias voltage across the MTJ junction with a right polarization could reduce the Hc of the magnetic layer adjacent to the MgO layer. A so-called voltage-controlled pSTT-MRAM has been proposed [W.-G. Wang et al., Natural Materials, Vol. 11, 64, 2012].

### BRIEF SUMMARY OF THE PRESENT INVENTION

The present invention is a method to make a three-terminal spin transfer torque magnetic random access memory (STT-MRAM) with magnetic reference layer at bottom and memory layer on the top. The first electrode (digital line) is connected to a magnetic reference layer at the bottom, and the second electrode is located at the middle memory layer which is connected to the underneath CMOS circuit through VIA and the third electrode is a voltage gate connecting to the top bit line which is used to reduce the write current when a voltage is applied between the top and middle electrode.

The memory cell further includes a circuitry coupled to the digital line positioned adjacent to selected ones of the plurality of magnetoresistive memory elements to supply a reading current or bi-directional spin polarized current to the MTJ stack, and coupled to the bit line configured to generate an electric field on the functional layer and accordingly to decrease the switching energy barrier of the recording layer. Thus magnetization of a recording layer can be readily switched or reversed to the direction in accordance with a direction of a current across the MTJ stack by applying a low spin transfer current.

The formation of such perpendicular pSTT-MRAM film stack includes deposition of a seed layer, a magnetic reference layer, a MgO dielectric layer, a magnetic memory layer, a dielectric insulating layer and a top electrode. Then, several photolithography patterning, etching and dielectric refill are used to form the entire memory cell.

The exemplary embodiments will be described hereinafter with reference to the accompanying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 Schematics of three-terminal spin torque transfer random access memory.

FIG. 2A Cross section view of the substrate with CMOS built-in (not shown).

FIG. 2B Top view of the substrate with CMOS built-in (not shown).

FIG. 3 Memory film stack deposited.

FIG. 4 First photolithography patterning, etching and dielectric ILD deposited by ALD.

FIG. 5 Top and bottom portion of ILD are removed by vertical milling.

FIG. 6 Conduction layer is plated connecting to VIA.

FIG. 7 Second photo lithography patterning and etching of top electrode

FIG. 8 Another ILD deposition by ALD.

FIG. 9 Top and bottom portion of ILD are removed by vertical milling.

FIG. 10 The exposed portion of memory layer is converted into non-magnetic conduction lead by Cr or B ion mixing.

FIG. 11 Dielectric refilling and CMP to form flat top surface.

FIG. 12 Top bit line is formed.

FIG. 13 Embodiment two—the first photolithography patterning & etching.

FIG. 14 Embodiment two—the etched areas are refilled with dielectric material.

FIG. 15 Embodiment two—the second photolithography patterning & etching.

FIG. 16 Embodiment two—an ILD is deposited to cover the etched surface.

FIG. 17A Embodiment two—low angle mill is used to remove the ILD from the top and bottom surface.

FIG. 17B Embodiment two—low angle mill is used to remove the ILD from the top and bottom surface.

FIG. 17C Embodiment two—low angle mill is used to remove the ILD from the top and bottom surface.

FIG. 17D Embodiment two—low angle mill is used to remove the ILD from the top and bottom surface.

FIG. 17E Embodiment two—low angle mill is used to remove the ILD from the top and bottom surface.

FIG. 17F Embodiment two—low angle mill is used to remove the ILD from the top and bottom surface.

FIG. 18 A pSTT-MRAM unit cell is formed.

### DETAILED DESCRIPTION OF THE INVENTION

A three-terminal p-STT-MRAM (FIG. 1) contains (counting from the bottom) a digital line (110), a magnetic reference layer (120), a MgO dielectric layer (130), a magnetic memory layer (140), a dielectric insulating layer (150) and an electrode (160) on the top. The middle magnetic memory layer (140) is connected to CMOS VIA through a conduction layer 170.

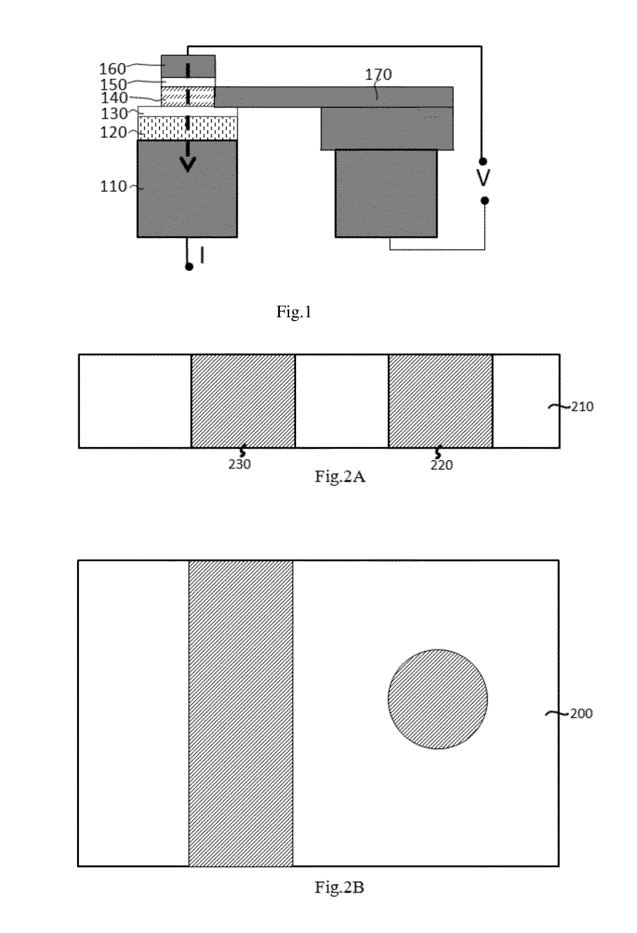

The fabrication process starts (FIG. 2A-cross section view and FIG. 2B-top view) from a substrate (210) containing a bottom digital line (230) and a VIA (220) which is connected to the bottom CMOS circuits already built in (not shown).

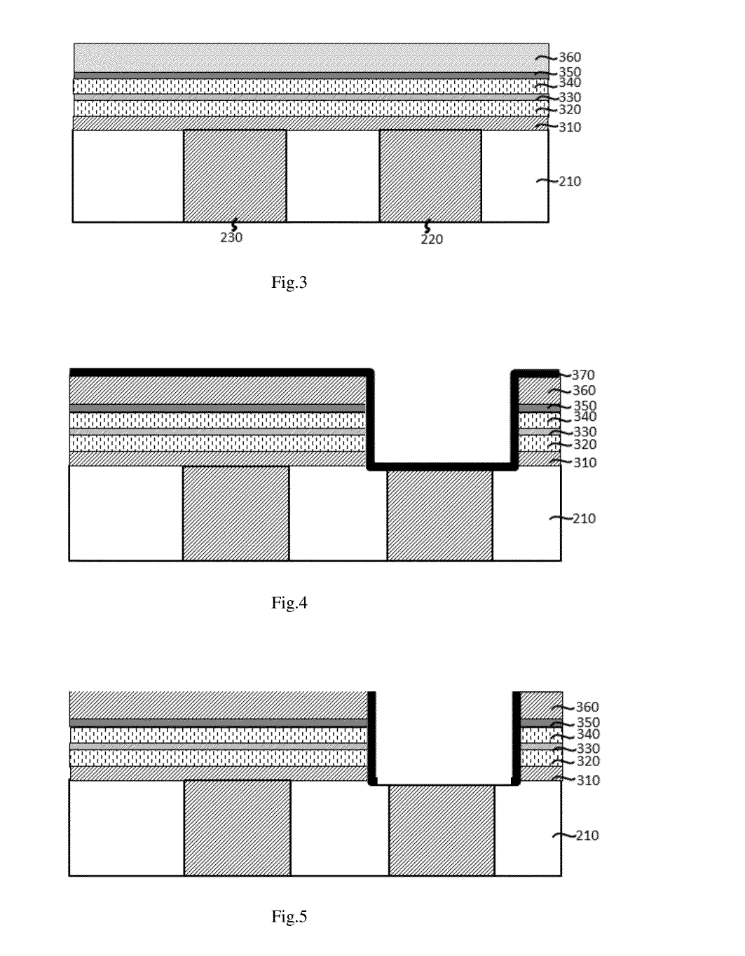

The first process starts (FIG. 3) from the deposition of seed layer (310) which promotes the formation of a perpendicularly polarized magnetic reference layer (320). A typical material system for such reference layer is [Co/Pd]n, [Co/Pt]n, [Co/Ni]n or [Co/Tb]n superlattice with a total thickness between 30 A-100 A, followed by a MgO dielectric layer (330) with a thickness of 10-15 A, a magnetic memory layer (340) containing either a single CoFeB or bi-layer of CoFeB/CoFe with a thickness of 10-30 A, an insulating layer (350) made of either a MgO layer, or, MgO/Al₂O₃ bi-layer with a thickness of 20-40 A, a top electrode layer (360) of either a single Ta layer or Ru/Ta bi-layer with a thickness of 200-400 A.

Then a high temperature anneal is performed to align each magnetic layers in their correct orientation and to reduce the stress resulting from deposition. Depending on how to connect the top memory layer to the VIA on the substrate, we have two different patterning and etching processes to be described in the following Embodiment one and two.

### Embodiment One

As shown in FIG. 4, a photolithography and etching is used to remove the memory multilayer to open a hole right on top of the VIA, and subsequently a dielectric insulating layer or so-called ILD (370) is conformally deposited over the exposed areas by a so-called atomic layer deposition (ALD) method.

Then a low angle milling or perpendicular sputter etching is used to remove the ILD film from the bottom and top flat area, leaving only the vertical wall still protected by the ILD (FIG. 5).

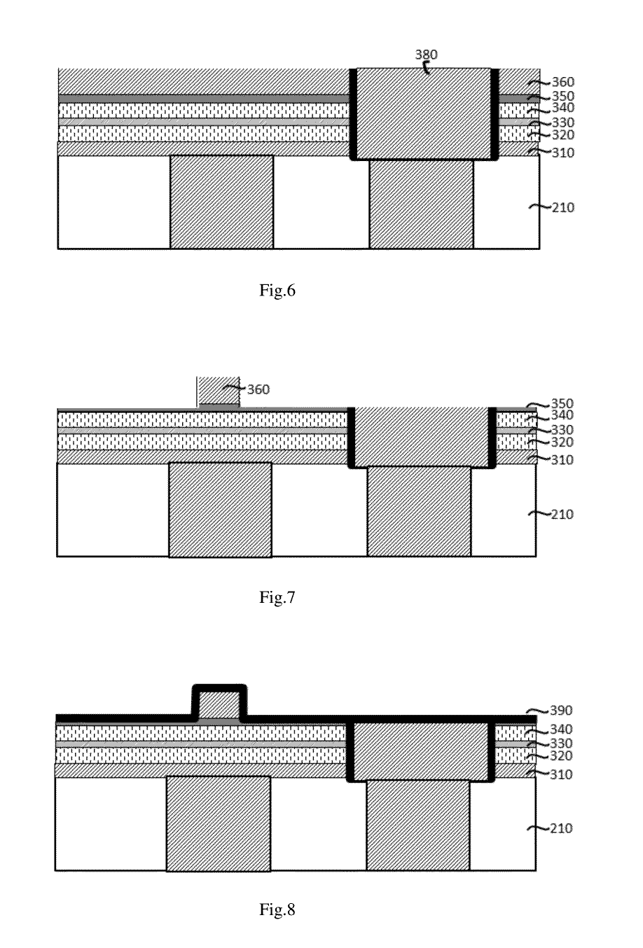

Then, by electric plating, the VIA hole is filled with a conducting material (380). Then, the top surface is flattened by a chemical mechanical polishing (CMP) process (FIG. 6).

Then, a second photolithography patterning and etching is used to form a hard mask pillar (360) cap, and the etching stops in the middle of top ILD layer (350) controlled by an end point detector (FIG. 7).

Then, another ILD is conformally deposition all over the exposed areas (FIG. 8), followed by low-angle milling or perpendicular sputtering etch to remove the newly grown ILD from the bottom and top flat areas and leaving on the vertical wall is still covered by the ILD (FIG. 9).

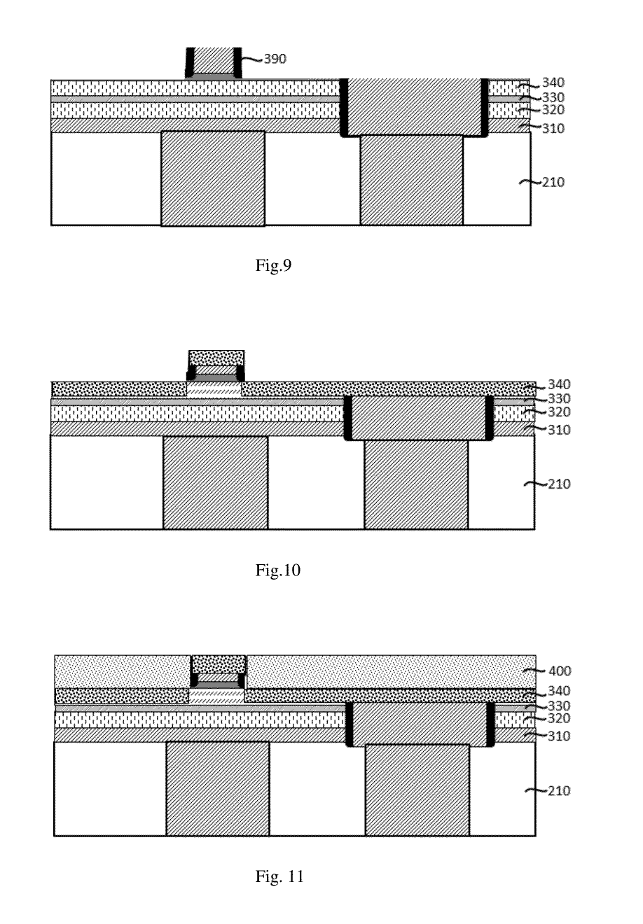

Then, ion implantation is used to add metallic ions into the exposed portion of top memory layer (340) to convert it into a non-magnetic but electrically conducting layer, which defines the lateral width of the memory cell (FIG. 10).

Then, dielectric material (such as SiO2 or Si3N4) is refilled in the etch valley, followed by a CMP to form a flat top surface (FIG. 11).

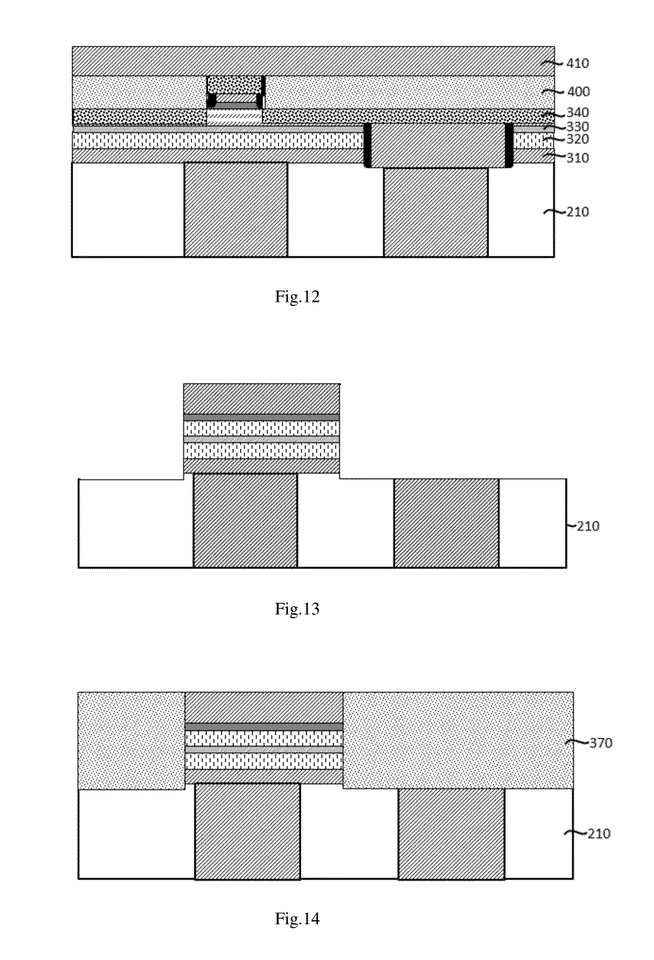

Finally, a top electrode is formed by deposition, photo patterning, milling/etching (FIG. 12). The as-formed memory cell has an advantage of wide base for the reference layer which could provide a stable pinning layer for the memory cell.

### Embodiment Two

In the second embodiment, the process starts after deposition of the magnetic multi-layer (FIG. 3). With a photolithography patterning, the majority of the memory film stack is removed and only the areas for the memory cell remain (FIG. 13).

Then, the etched area is refilled by dielectrics (370, SiO2 or Si3N4) and surface is flattened by CMP (FIG. 14).

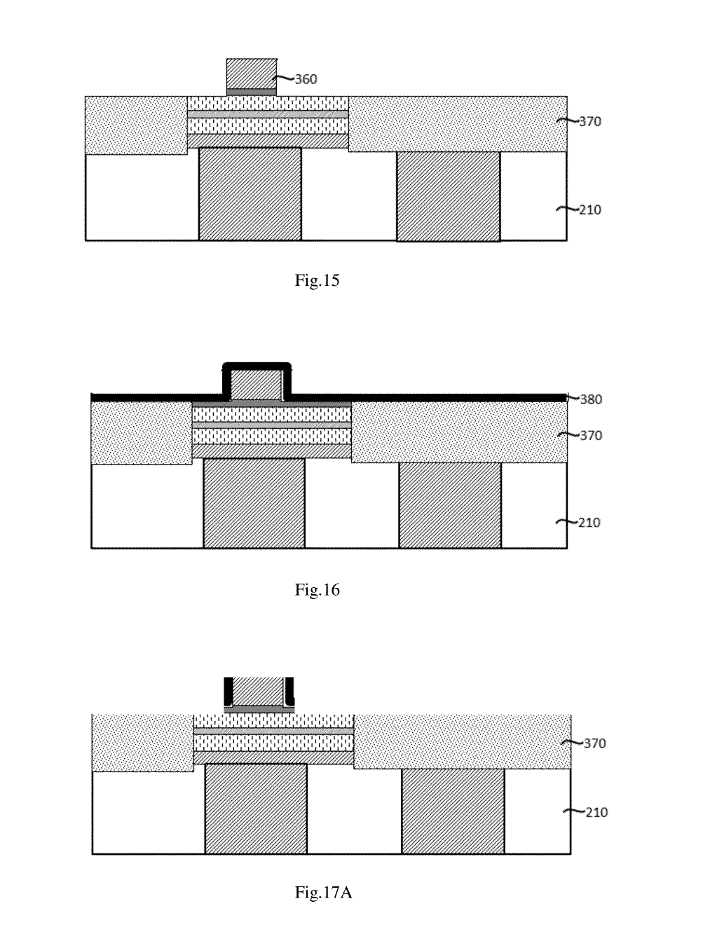

Then, a second photo patterning and etching/milling is used to form a memory pillar cap (360) and the etching stop in the middle of the top ILD layer (FIG. 15).

Then an ILD layer (380) is conformally deposited all around the etched surface by ALD method (FIG. 16).

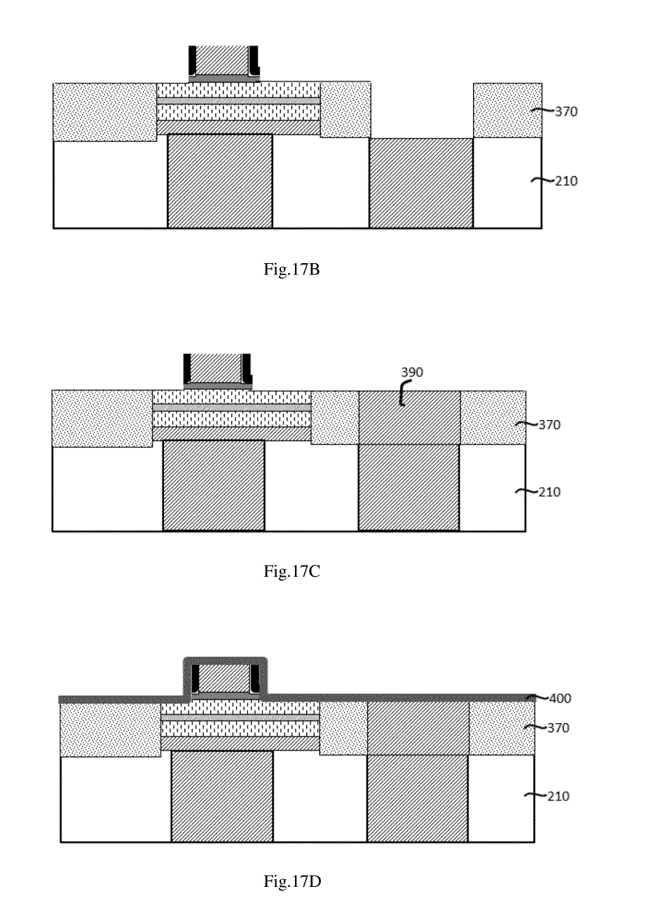

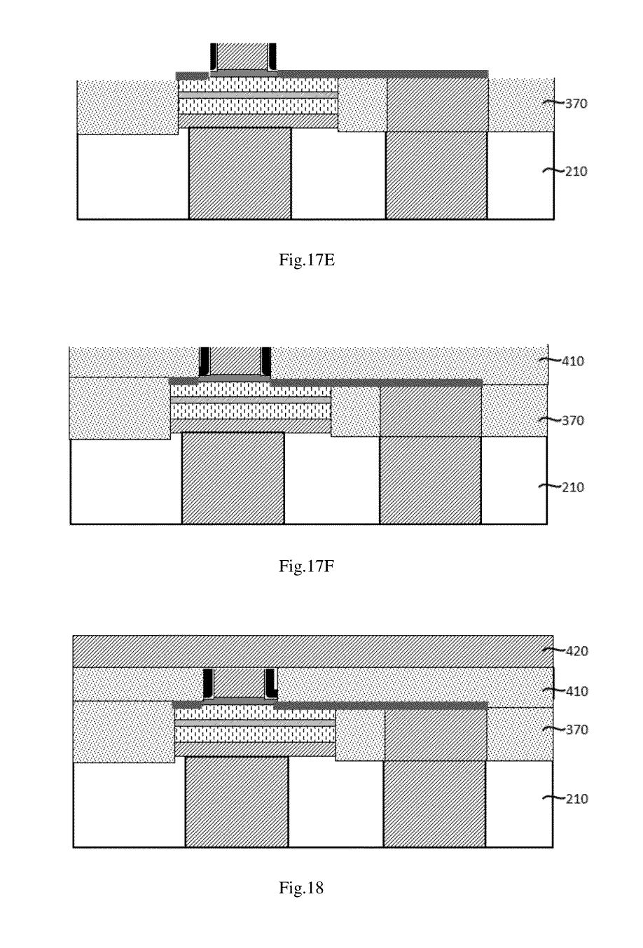

Followed by a low angle mill/or perpendicular sputtering etch to remove the ILD from the top and bottom flat portion of the area, leaving on the vertical wall still covered by the ILD (FIG. 17A).

Then, a photolithography and etchin is used to remove dielectric layer and open a hole on top of the VIA (FIG. 17B).

Then, an electric plating is used to fill a conductive material (390) in the just opened hole (FIG. 17C).

Then, a metal layer (400) is uniformly deposited on the top surface by an atomic layer deposition method (FIG. 17D).

Then, a photolithography and etching is used to remove the metal layer from the wall of MTJ and the flat areas exposed by the photoresist, and leave the portion connecting between the memory layer and the VIA remain which serve as the electric path between the middle memory layer and the underneath CMOS circuit through the VIA (FIG. 17E).

Then, a dielectric layer (SiO2 or SiN) is refilled (410) the exposed areas by PECVD, followed by a CMP to flatten the surface (FIG. 17F).

Finally, similar to the process described in Embodiment one, a top electrode (420) is formed by deposition, photo patterning, milling/etching (FIG. 18).

1. A three-terminal spin torque transfer magnetic random access memory contains a core memory film stack of (counting from the bottom) a magnetic reference layer, a dielectric tunneling layer, a memory layer, a second dielectric insulating layer, a top electrode;

2. The element of claim 1, wherein the first electrode is connected to the bottom reference layer, the second electrode is connected to the middle memory layer, and the third electrode is on the top;

3. The element of claim 2, wherein the magnetization of the bottom reference layer is perpendicular to the plane, and magnetization of the memory layer is modulated by the voltage between the second and third electrodes, which could be perpendicular to the plane or lie in the plane;

4. The element of claim 2, wherein both the write and read currents flow through the first and the second electrode;

5. The element of claim 4, wherein the write current can be reduced by applying a voltage between the second and third electrodes;

6. The element of claim 1, wherein the bottom magnetic reference layer is [Co/Pd]n, [Co/Pt]n, [Co/Tb]n, (Co/Ni)n superlattice with a thickness between 20-60 A;

7. The element of claim 1, wherein the dielectric tunneling layer between the reference layer and memory layer is MgO and has a thickness between 10-15 A;

8. The element of claim 1, wherein the memory layer is CoFeB: 10-20 A or CoFeB/CoFe bi-layer with CoFe as interface dusting layer (2-5 A);

9. The element of claim 1, wherein the insulating layer between the middle memory layer and top electrode is a single MgO layer or a bi-layer of Al₂O₃/MgO with a thickness between 20-40 A;

10. The element of claim 1, wherein the top capping layer is Ru, Ta or Ru/Ta bi-layer with a thickness between 100-200 A;

11. The element of claim 1, wherein the entire memory film stack is deposited by physical vapor deposition in one vacuum pump down on the device substrate with CMOS control circuits already built in;

12. The element of claim 11, wherein a photo patterning and etch are used to create a hole to the VIA;

13. The element of claim 12, wherein the entire surface is conformally covered with an insulating layer (ILD) of Al₂O₃ or HfO2 deposited by atomic layer deposition (ALD) with a film thickness of 40-80 A;

14. The element of claim 13, wherein a low angle milling or etching is used to remove the top and bottom ILD to open the VIA area;

15. The element of claim 14, wherein the vertical wall of the VIA is still covered by the remaining ILD;

16. The element of claim 15, wherein the opened VIA area is refilled with a conducting material by electrical plating;

17. The element of claim 16, wherein the second photolithography patterning and etching are used to create a cap for memory cell;

18. The element of claim 17, wherein an ion implantation is used to add conducting metallic material, V, Cr, Cu, Al into the exposed area of the memory layer;

19. The element of claim 18, wherein the ion implanted area of the memory layer lost its magnetic property but electrically conducting;

20. The element of claim 19, wherein the lateral width of the memory cell is defined by the top capping layer;

21. The element of claim 20, wherein a conducting path is formed between the middle memory layer to the VIA;

22. The element of claim 21, wherein a voltage gate is formed between the top electrode and the middle memory layer;

23. The element of claim 22, wherein the current path for memory writing and reading is formed between the bottom (first) and top (third) electrode.
